(19) United States
(12) Patent Application Publication
(10) Pub. No.: US 2009/0269706 A1
(43) Pub. Date: Oct. 29, 2009

(54) METHOD FOR FORMING RESIST PATTERN

(75) Inventors: Takeyoshi Mimura, Kawasaki-shi (JP); Tomohiko Hayashi, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 11/813,512

(22) PCT Filed: Dec. 13, 2005
(86) PCT No.: PCT/JP05/22874

§ 371 Date: Jul. 6, 2007

(30) Foreign Application Priority Data
Jan. 26, 2005 (JP) 2005-017968

(51) Int. Cl. G03F 7/20

(52) U.S. Cl. 430/325

(57) ABSTRACT

A method for forming a resist pattern that includes the steps of: forming a resist film on a substrate using a resist composition including a resin component (A) that exhibits changed alkali solubility under the action of acid and an acid generator component (B) that generates acid upon exposure; selectively exposing the resist film; and developing the resist film using an alkali developing solution for a developing time of less than 30 seconds, thereby forming a resist pattern.

### TECHNICAL FIELD

The present invention relates to a method for forming a resist pattern.

Priority is claimed on Japanese Patent Application No. 2005-017968, filed Jan. 26, 2005, the content of which is incorporated herein by reference.

### BACKGROUND ART

In recent years, in the production of semiconductor elements and liquid crystal display elements, advances in lithography techniques have lead to rapid progress in the field of miniaturization. Typically, these miniaturization techniques involve shortening the wavelength of the exposure light source. Conventionally, ultraviolet radiation typified by g-line and i-line radiation has been used, but nowadays KrF excimer lasers (248 nm) are the main light source used in mass production, and ArF excimer lasers (193 nm) are now also starting to be introduced in mass production. Furthermore, research is also being conducted into lithography techniques that use F₂ excimer lasers (157 nm), EUV (extreme ultra violet radiation), and EB (electron beams) and the like as the light source (radiation source).

Resists for use with these types of short wavelength light sources require a high resolution capable of reproducing patterns of minute dimensions, and a high level of sensitivity relative to these types of short wavelength light sources. One example of a known resist that satisfies these conditions is a chemically amplified resist, which includes a base resin and an acid generator (hereafter referred to as a PAG) that generates acid upon exposure, and these chemically amplified resists include positive resists in which the alkali solubility of the exposed portions increases, and negative resists in which the alkali solubility of the exposed portions decreases.

Until recently, polyhydroxystyrene (PHS) based resins, which exhibit high transparency relative to a KrF excimer laser (248 nm), have been used as the base resin of chemically amplified resists. However because PHS-based resins contain aromatic rings such as benzene rings, their transparency is inadequate for light with wavelengths shorter than 248 nm, such as light of 193 nm. Accordingly, chemically amplified resists that use a PHS-based resin as the base resin component suffer from low levels of resolution in processes that, for example, use light of 193 nm.

As a result, resins that contain structural units derived from acrylate esters (namely, acrylic resins), which offer excellent transparency in the vicinity of 193 nm, are now widely used as the base resins for resists used in processes that use light with a wavelength shorter than 248 nm, such as an ArF excimer laser (193 nm) or the like. For example, in the case of positive resists, then as disclosed in patent reference 1, resins containing structural units derived from tertiary ester compounds of acrylic acid in which the hydrogen atom of the carboxyl group has been substituted with an acid-dissociable, dissolution-inhibiting group, such as 2-alkyl-2-adamantyl (meth)acrylates, are typically used.

By using these types of materials and the most up-to-date techniques using ArF excimer lasers, fine resist patterns with a pattern dimension of approximately 90 nm are currently able to be formed, but in the future, it is assumed that even finer pattern formation will be required.

However, when a chemically amplified resist is used to form a resist pattern, although a very fine resist pattern can be formed, a problems arises in that pattern collapse becomes more likely. Pattern collapse becomes more prevalent as the pattern becomes finer.

Methods that are used for improving the occurrence of pattern collapse include (1) a method of optimizing the materials so as to suppress pattern collapse (for example, see patent reference 2), and (2) a method in which, during pattern formation, following substitution of the liquid on the surface of the substrate with a special liquid, supercritical drying is used (for example, see patent reference 3).

[Patent Reference 1]

Japanese Patent (Granted) Publication No. 2,881,969

[Patent Reference 2]

International Patent Publication No. WO 04/108780 pamphlet

[Patent Reference 3]

Japanese Unexamined Patent Application, First Publication No. 2004-233953

### DISCLOSURE OF INVENTION

However, with these methods, pattern collapse during formation of ultra fine patterns such as those with a pattern dimension of no more than 90 nm, and particularly fine patterns with a pattern dimension of 65 nm or less, cannot be adequately suppressed.

Furthermore, the research and development, and the processes associated with these methods require considerable outlays in terms of time, effort, and cost. Moreover, another problem arises in that optimization of the materials can have an adverse effect on the lithography characteristics such as the resolution.

The present invention addresses the circumstances described above, with an object of providing a method for forming a resist pattern that enables pattern collapse during the formation of very fine patterns to be readily prevented.

As a result of intensive investigation, the inventors of the present invention discovered that by restricting the developing time during resist pattern formation to less than 30 seconds, the problems described above could be resolved, and they were therefore able to complete the present invention. In other words, the present invention provides a method for forming a resist pattern that includes the steps of forming a resist film on a substrate using a resist composition including a resin component (A) that exhibits changed alkali solubility under the action of acid and an acid generator component (B) that generates acid upon exposure, selectively exposing the resist film, and developing the resist film using an alkali developing solution for a developing time of less than 30 seconds, thereby forming a resist pattern.

In this description and in the claims, the term “exposure” is used as a general concept that includes irradiation with any form of radiation, including irradiation with an electron beam.

According to the present invention, there is provided a method for forming a resist pattern that enables pattern collapse during the formation of very fine patterns to be readily prevented.

### BEST MODE FOR CARRYING OUT THE INVENTION

### [Method for Forming Resist Pattern]

As described above, in a method for forming a resist pattern according to the present invention, the developing time during resist pattern formation must be less than 30 seconds. Simply by conducting the simple operation of restricting the developing time to less than 30 seconds, pattern collapse can be suppressed.

There are no particular restrictions on the developing time, provided it is less than 30 seconds. However, in terms of achieving superior effects for the present invention, the developing time is preferably no longer than 25 seconds, even more preferably no longer than 20 seconds, and is most preferably no longer than 15 seconds. Furthermore, from the viewpoint of ensuring adequate solubility of the resist film, the lower limit for the developing time is preferably at least 10 seconds.

Conventional developing times are typically within a range from 30 to 60 seconds.

With the exception of the developing time, the method for forming a resist pattern according to the present invention can adopt conventionally known methods, and can be conducted, for example, in the manner described below.

First, a resist composition is applied to a substrate such as a silicon wafer using a spinner or the like, and a prebake (PAB) treatment is then conducted to form a resist film.

An organic or inorganic anti-reflective film may be provided between the substrate and the resist film. Furthermore, an organic anti-reflective film may be provided on top of the resist film, and in such cases the anti-reflective film provided on top of the resist film is preferably soluble in an alkali developing solution.

Subsequently, selective exposure is conducted by irradiating the resist film with radiation such as an ArF excimer laser through a desired mask pattern.

There are no particular restrictions on the type of radiation used for the exposure, and an ArF excimer laser, KrF excimer laser, F₂ excimer laser, or other radiation such as EUV (extreme ultra violet), VUV (vacuum ultra violet), EB (electron beam), X-ray or soft X-ray radiation can be used. In the method for forming a resist pattern according to the present invention, conducting the exposure using an ArF excimer laser is particularly desirable, as it enables the formation of a very fine pattern with a pattern dimension of no more than 90 nm, and even 65 nm or less.

Next, following completion of the exposure step, PEB (post exposure baking) is conducted, and a developing treatment using an alkali developing solution is then conducted for the developing time described above.

There are no particular restrictions on the alkali developing solution used, and typically employed alkali developing solutions can be used. As the alkali developing solution, compounds represented by a general formula NZ¹Z²Z³Z⁴OH (wherein, Z¹ to Z⁴ each represent, independently, an alkyl group or alkanol group of 1 to 5 carbon atoms) are preferred, and specific examples include alkali aqueous solutions prepared by dissolving an organic alkali such as tetramethylammonium hydroxide (TMAH), trimethylmonoethylammonium hydroxide, dimethyldiethylammonium hydroxide, monomethyltriethylammonium hydroxide, trimethylmonopropylammonium hydroxide or trimethylmonobutylammonium hydroxide in water.

There are no particular restrictions on the alkali concentration within the alkali developing solution, which may be any concentration typically used within developing solutions, and although the concentration varies depending on the resist used, in terms of suppressing pattern collapse while enabling formation of a fine pattern, the concentration is preferably within a range from 0.1 to 10% by weight, even more preferably from 0.5 to 5% by weight, and is most preferably from 2.0 to 3.5% by weight.

The alkali developing solution may also include, in addition to the alkali described above and according to need, the types of additive components typically used within alkali developing solutions for conventional resists, such as wetting agents, stabilizers, dissolution assistants, and surfactants. These additive components may be added either alone, or in combinations of 2 or more different components.

The effect of the present invention is not dependent on the type of alkali developing solution used for developing. It is surmised that the reason for this observation is that the contact time with the hydrophilic liquid that acts as the alkali developing solution is the major factor in suppressing pattern collapse.

The types of developing devices typically used for developing resists can be used for the developing step.

The effect of the present invention is not dependent on the type of developing device used for developing. In a similar manner to that described above, it is surmised that the reason for this observation is that the contact time with the hydrophilic liquid that acts as the alkali developing solution is the major factor in suppressing pattern collapse.

The developing temperature may be the temperature within the clean room in which mass production of the semiconductor elements is conducted, and the temperature is preferably within a range from 10 to 30° C., and even more preferably from 15 to 25° C.

The most preferred conditions in terms of achieving a favorable depth of focus (DOF) and suppressing pattern collapse involve conducting the developing at a temperature within a range from 22 to 25° C., and particularly at 23° C., for 10 to 15 seconds within a 2.38% by weight aqueous solution of TMAH.

Following the developing treatment, a rinse is preferably conducted using pure water, thereby washing away the developing solution left on the substrate and those portions of the resist composition that have been dissolved by the developing solution. This rinse can be conducted, for example, by dripping or spraying water onto the surface of the substrate while it is rotated.

In this manner, a resist pattern that is faithful to the mask pattern can be obtained.

With the exception of the developing time, these steps can be conducted using known techniques. The operating conditions and the like are preferably set appropriately in accordance with the makeup and the characteristics of the resist composition being used.

### (Resist Composition)

A resist composition used in the method for forming a resist pattern according to the present invention is a so-called chemically amplified resist composition, including a resin component (A) (hereafter referred to as the component (A)) that exhibits changed alkali solubility under the action of acid, and an acid generator component (B) (hereafter referred to as the component (B)) that generates acid upon exposure. Using a chemically amplified resist composition enables an ultra fine resist pattern to be formed.

The chemically amplified resist composition may be either a positive composition or a negative composition, and can be selected from known resists in accordance with the light source used for the exposure. In the present invention, a positive composition is preferred.

There are no particular restrictions on the component (A), and one or more of the alkali-soluble resins, or resins that can be converted to an alkali-soluble state, that have been proposed as resins for chemically amplified resists can be used. The former case describes a so-called negative resist composition, and the latter case describes a so-called positive resist composition.

In the case of a negative composition, a cross-linking agent is added to the resist composition together with the alkali-soluble resin. Then, during resist pattern formation, when acid is generated from the component (B) upon exposure, the action of this acid causes cross-linking to occur between the alkali-soluble resin and the cross-linking agent, causing the composition to become alkali-insoluble.

As the alkali-soluble resin, resins containing structural units derived from at least one compound selected from amongst α-(hydroxyalkyl) acrylic acids and lower alkyl esters of α-(hydroxyalkyl) acrylic acids enable the formation of resist patterns with minimal swelling, and are consequently preferred. The alkyl group within these lower alkyl esters is preferably a group of 1 to 5 carbon atoms.

Furthermore, as the cross-linking agent, typically the use of an amino-based cross-linking agent that exhibits poor solubility in immersion exposure solvents, such as a glycoluril containing a methylol group or alkoxymethyl group, and particularly a butoxymethyl group, enables the formation of a resist pattern with minimal swelling, and is consequently preferred.

The blend quantity of the cross-linking agent is preferably within a range from 1 to 50 parts by weight per 100 parts by weight of the alkali-soluble resin.

In the case of a positive composition, the component (A) is an alkali-insoluble compound containing so-called acid-dissociable, dissolution-inhibiting groups, and when acid is generated from the component (B) upon exposure, this acid causes the acid-dissociable, dissolution-inhibiting groups to dissociate, causing the component (A) to become alkali-soluble.

Consequently, during resist pattern formation, by selectively exposing the resist composition applied to the surface of the substrate, the alkali solubility of the exposed portions is increased, meaning alkali developing can then be conducted.

In the present invention, as described above, exposure is preferably conducted using an ArF excimer laser, and consequently the component (A) is preferably the type of resist composition resin component typically used in processes that use an ArF excimer laser as the exposure light source. Examples of preferred forms of the resin component, for both positive and negative compositions, include resins containing structural units (a) derived from acrylate esters, which exhibit excellent transparency relative to ArF excimer lasers. Because resins containing structural units (a) also exhibit excellent alkali solubility, a fine pattern with excellent uniformity can be formed even with a developing time of less than 30 seconds.

In the present invention, the component (A) preferably includes structural units (a) as the principal component. Here the term “principal component” means that relative to the combined total of all the structural units that constitute the component (A), the structural units (a) represent the largest proportion, and this proportion is preferably at least 50 mol %, is even more preferably within a range from 70 to 100 mol %, and is most preferably 100 mol %.

In this description and in the claims, a “structural unit” refers to a monomer unit that contributes to the formation of a resin component (polymer compound).

A “structural unit derived from an acrylate ester” refers to a structural unit formed by cleavage of the ethylenic double bond of an acrylate ester. The term “acrylate ester” is deemed to include not only the acrylate ester, in which a hydrogen atom is bonded to the α-position carbon atom, but also structures in which a substituent group (an atom or group other than a hydrogen atom) is bonded to the α-position. Examples of this substituent group include a halogen atom such as a fluorine atom, an alkyl group, or a haloalkyl group. Unless stated otherwise, the term “α-position” or “α-position carbon atom” of a structural unit derived from an acrylate ester refers to the carbon atom to which the carbonyl group is bonded.

An “alkyl group”, unless stated otherwise, includes straight-chain, branched-chain, and cyclic monovalent saturated hydrocarbon groups.

In the present invention, the resist composition is preferably a positive composition, and the component (A) used in the resist composition is preferably a resin containing a structural unit (a1) derived from an acrylate ester that contains an acid-dissociable, dissolution-inhibiting group.

In the structural unit (a1), a hydrogen atom or a lower alkyl group is bonded to the α-position of the acrylate ester.

The lower alkyl group bonded to the α-position of the acrylate ester is preferably an alkyl group of 1 to 5 carbon atoms, and is preferably a straight-chain or branched-chain alkyl group, and suitable examples include a methyl group, ethyl group, propyl group, isopropyl group, n-butyl group, isobutyl group, tert-butyl group, pentyl group, isopentyl group, or neopentyl group. Of these, a methyl group is preferred industrially.

Either a hydrogen atom or a methyl group is preferably bonded to the α-position of the acrylate ester, and a methyl group is particularly desirable.

The acid-dissociable, dissolution-inhibiting group of the structural unit (a1) has an alkali dissolution-inhibiting effect that renders the entire component (A) alkali-insoluble prior to exposure, but then dissociates following exposure as a result of the action of the acid generated from the component (B), causing the entire component (A) to change to an alkali-soluble state.

The acid-dissociable, dissolution-inhibiting group can use any of the multitude of groups that have been proposed for the resins used within resist compositions designed for use with ArF excimer lasers. Generally, groups that form a cyclic or chain-like tertiary alkyl ester, or a cyclic or chain-like alkoxyalkyl group with the carboxyl group of the (meth)acrylate ester are the most widely known. Here, the term “(meth)acrylate ester” is a generic term that includes the acrylate ester and/or the methacrylate ester.

Here, a “group that forms a tertiary alkyl ester” describes a group that forms an ester by substituting the hydrogen atom of the acrylic acid carboxyl group. In other words, a structure in which the tertiary carbon atom of a chain-like or cyclic tertiary alkyl group is bonded to the oxygen atom at the terminal of the carbonyloxy group (—C(O)—O—) of the acrylate ester. In this tertiary alkyl ester, the action of acid causes cleavage of the bond between the oxygen atom and the tertiary carbon atom.

A tertiary alkyl group refers to an alkyl group that includes a tertiary carbon atom.

The group that forms a chain-like tertiary alkyl ester is preferably a group of 4 to 10 carbon atoms, and suitable examples include a tert-butyl group or tert-amyl group. Examples of groups that form a cyclic tertiary alkyl group include the same groups as those exemplified below in relation to the “acid-dissociable, dissolution-inhibiting group that contains an alicyclic group”.

Furthermore, “a cyclic or chain-like alkoxyalkyl group” forms an ester by substitution with the hydrogen atom of a carboxyl group. In other words, a structure is formed in which the alkoxyalkyl group is bonded to the oxygen atom at the terminal of the carbonyloxy group (—C(O)—O—) of the acrylate ester. In this structure, the action of acid causes cleavage of the bond between the oxygen atom and the alkoxyalkyl group.

As this type of cyclic or chain-like alkoxyalkyl group, a group of 2 to 20 carbon atoms is preferred, and specific examples include a 1-methoxymethyl group, 1-ethoxyethyl group, 1-isopropoxyethyl group, 1-cyclohexyloxyethyl group, 2-adamantoxymethyl group, 1-methyladamantoxymethyl group, 4-oxo-2-adamantoxymethyl group, 1-adamantoxyethyl group, or 2-adamantoxyethyl group.

As the structural unit (a1), structural units that include an acid dissociable, dissolution inhibiting group that contains a cyclic group, and particularly an aliphatic cyclic group, are preferred.

In this description and in the claims, the term “aliphatic” is a relative concept used in relation to the term “aromatic”, and defines a group or compound or the like that contains no aromaticity. The term “aliphatic cyclic group” describes a monocyclic group or polycyclic group that contains no aromaticity.

The aliphatic cyclic group may be either monocyclic or polycyclic, and can be selected appropriately from the multitude of groups proposed for use within ArF resists and the like. From the viewpoint of ensuring favorable etching resistance, a polycyclic alicyclic group is preferred. Furthermore, the alicyclic group is preferably a hydrocarbon group, and is even more preferably a saturated hydrocarbon group (alicyclic group). The number of carbon atoms within the aliphatic cyclic group is preferably within a range from 4 to 30.

Examples of suitable monocyclic alicyclic groups include groups in which one hydrogen atom has been removed from a cycloalkane. Examples of suitable polycyclic alicyclic groups include groups in which one hydrogen atom has been removed from a bicycloalkane, tricycloalkane or tetracycloalkane or the like.

Specifically, examples of suitable monocyclic alicyclic groups include a cyclopentyl group or cyclohexyl group. Examples of suitable polycyclic alicyclic groups include groups in which one hydrogen atom has been removed from a polycycloalkane such as adamantane, norbornane, isobornane, tricyclodecane or tetracyclododecane.

Of these groups, an adamantyl group in which one hydrogen atom has been removed from adamantane, a norbornyl group in which one hydrogen atom has been removed from norbornane, a tricyclodecanyl group in which one hydrogen atom has been removed from tricyclodecane, and a tetracyclododecanyl group in which one hydrogen atom has been removed from tetracyclododecane are preferred industrially.

More specifically, the structural unit (a1) is preferably at least one unit selected from the general formulas (I′) to (III′) shown below.

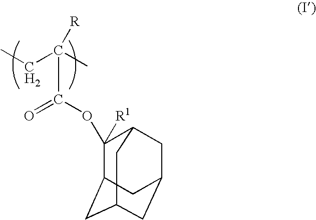

[In the formula (I′), R represents a hydrogen atom or a lower alkyl group, and R¹ represents a lower alkyl group.]

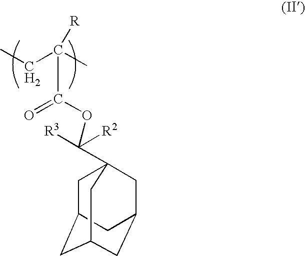

[In the formula (II′), R represents a hydrogen atom or a lower alkyl group, and R² and R³ each represent, independently, a lower alkyl group.]

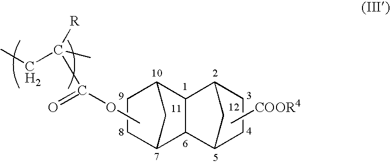

[In the formula (III′), R represents a hydrogen atom or a lower alkyl group, and R⁴ represents a tertiary alkyl group.]

In the formulas (I′) to (III′), the hydrogen atom or lower alkyl group represented by R is as described above in relation to the hydrogen atom or lower alkyl group bonded to the α-position of an acrylate ester.

The lower alkyl group of R¹ is preferably a straight-chain or branched alkyl group of 1 to 5 carbon atoms, and specific examples include a methyl group, ethyl group, propyl group, isopropyl group, n-butyl group, isobutyl group, pentyl group, isopentyl group, and neopentyl group. Of these, a methyl group or ethyl group is preferred from the viewpoint of industrial availability.

The lower alkyl groups of R² and R³ each preferably represent, independently, a straight-chain or branched alkyl group of 1 to 5 carbon atoms. Of the various possibilities, those cases in which R² and R³ are both methyl groups are preferred industrially. A structural unit derived from 2-(1-adamantyl)-2-propyl acrylate is a specific example.

Furthermore, the group R⁴ is preferably a chain-like tertiary alkyl group or a cyclic tertiary alkyl group. The chain-like tertiary alkyl group is preferably a group of 4 to 10 carbon atoms, and specific examples include a tert-butyl group or tert-amyl group, although a tert-butyl group is preferred industrially.

Examples of cyclic tertiary alkyl groups include the same groups as those exemplified above in relation to the “acid-dissociable, dissolution-inhibiting group that contains an aliphatic cyclic group”, and groups of 4 to 20 carbon atoms are preferred, with specific examples including a 2-methyl-2-adamantyl group, 2-ethyl-2-adamantyl group, 2-(1-adamantyl)-2-propyl group, 1-ethylcyclohexyl group, 1-ethylcyclopentyl group, 1-methylcyclohexyl group or 1-methylcyclopentyl group.

Furthermore, the group —COOR⁴ may be bonded to either position 3 or 4 of the tetracyclododecanyl group shown in the formula, although the bonding position cannot be further specified. Furthermore, the carboxyl group residue of the acrylate structural unit may be bonded to either position 8 or 9 within the formula, although similarly, the bonding position cannot be further specified.

The structural unit (a1) may use either a single structural unit, or a combination of two or more different structural units.

The proportion of the structural unit (a1) within the component (A), relative to the combined total of all the structural units that constitute the component (A), is preferably within a range from 20 to 60 mol %, even more preferably from 30 to 50 mol %, and is most preferably from 35 to 45 mol %. By ensuring that this proportion is at least as large as the lower limit of the above range, a favorable pattern can be obtained, whereas ensuring that the proportion is no greater than the upper limit of the above range enables a favorable balance to be achieved with the other structural units.

In the present invention, the component (A) preferably also includes, in addition to the structural unit (a1) described above, a structural unit (a2) derived from an acrylate ester that contains a lactone ring. The structural unit (a2) is effective in improving the adhesion of the resist film to the substrate, and enhancing the hydrophilicity of the component (A) relative to the developing solution.

In the structural unit (a2), a lower alkyl group or a hydrogen atom is bonded to the α-position carbon atom. The lower alkyl group bonded to the α-position carbon atom is as described above for the structural unit (a1), and is preferably a methyl group.

Examples of the structural unit (a2) include structural units in which a monocyclic group formed from a lactone ring or a polycyclic cyclic group that includes a lactone ring is bonded to the ester side-chain portion of an acrylate ester. The term lactone ring refers to a single ring containing a —O—C(O)— structure, and this ring is counted as the first ring. Accordingly, in this description, the case in which the only ring structure is the lactone ring is referred to as a monocyclic group, and groups containing other ring structures are described as polycyclic groups regardless of the structure of the other rings.

The structural unit (a2) is preferably a unit of 4 to 20 carbon atoms, and examples include units that contain a monocyclic group in which one hydrogen atom has been removed from γ-butyrolactone, and units that contain a polycyclic group in which one hydrogen atom has been removed from a lactone ring-containing bicycloalkane.

Specifically, the structural unit (a2) is preferably at least one unit selected from general formulas (IV′) through (VII′) shown below.

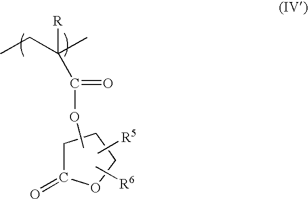

[In the formula (IV′), R represents a hydrogen atom or a lower alkyl group, and R⁵ and R⁶ each represent, independently, a hydrogen atom or a lower alkyl group.]

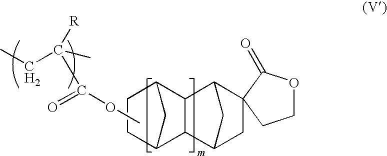

[In the formula (V′), R represents a hydrogen atom or a lower alkyl group, and m represents either 0 or 1.]

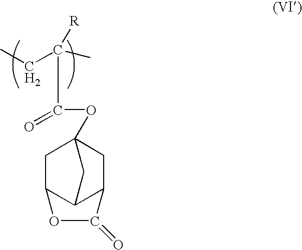

[In the formula (VI′), R represents a hydrogen atom or a lower alkyl group.]

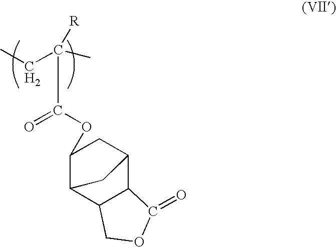

[In the formula (VII′), R represents a hydrogen atom or a lower alkyl group.]

In the formulas (IV′) to (VII′), R is as described above for the formulas (I′) to (III′).

In the formula (IV′), R⁵ and R⁶ each represent, independently, a hydrogen atom or a lower alkyl group, and preferably a hydrogen atom. Suitable lower alkyl groups for the groups R⁵ and R⁶ are preferably straight-chain or branched alkyl groups of 1 to 5 carbon atoms, and specific examples include a methyl group, ethyl group, propyl group, isopropyl group, n-butyl group, isobutyl group, tert-butyl group, pentyl group, isopentyl group, and neopentyl group. A methyl group is preferred industrially.

Furthermore, amongst the structural units represented by the general formulas (IV′) through (VII′), structural units represented by the general formula (IV′) are preferred in terms of reducing defects, and of the possible structural units represented by the formula (IV′), α-methacryloyloxy-γ-butyrolactone, in which R is a methyl group, R⁵ and R⁶ are both hydrogen atoms, and the position of the ester linkage between the methacrylate ester and the γ-butyrolactone is at the α-position of the lactone ring, is the most desirable.

The structural unit (a2) may use either a single structural unit, or a combination of two or more different structural units.

The proportion of the structural unit (a2) within the component (A), relative to the combined total of all the structural units that constitute the component (A), is preferably within a range from 20 to 60 mol %, even more preferably from 20 to 50 mol %, and is most preferably from 30 to 45 mol %. Ensuring that this proportion is at least as large as the lower limit of the above range improves the lithography characteristics, whereas ensuring that the proportion is no greater than the upper limit of the above range enables a favorable balance to be achieved with the other structural units.

In the present invention, the component (A) preferably also includes, either in addition to the structural unit (a1) described above or in addition to the structural units (a1) and (a2), a structural unit (a3) derived from an acrylate ester that contains a polar group-containing polycyclic group.

Including the structural unit (a3) increases the hydrophilicity of the entire component (A), thereby improving the affinity with the developing solution, improving the alkali solubility within the exposed portions of the resist, and contributing to an improvement in the resolution.

In the structural unit (a3), a lower alkyl group or a hydrogen atom is bonded to the α-position carbon atom. The lower alkyl group bonded to the α-position carbon atom is as described above for the structural unit (a1), and is preferably a methyl group.

Examples of the polar group include a hydroxyl group, cyano group, carboxyl group, or amino group or the like, although a hydroxyl group is particularly preferred.

The polycyclic group is preferably a group of 4 to 20 carbon atoms, and suitable examples include polycyclic groups selected from amongst the aliphatic cyclic groups exemplified above in relation to the “acid-dissociable, dissolution-inhibiting group that contains an aliphatic cyclic group”.

The structural unit (a3) is preferably at least one unit selected from the general formulas (VIII′) through (IX′) shown below.

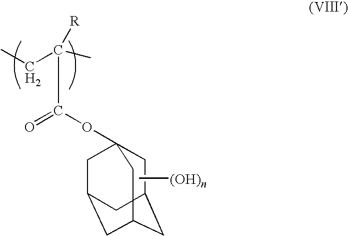

[In the formula (VIII′), R represents a hydrogen atom or a lower alkyl group, and n represents an integer from 1 to 3.]

In the formula (VIII′), R is as described above for the formulas (I′) to (III′).

Of these units, structural units in which n is 1, and the hydroxyl group is bonded to position 3 of the adamantyl group are preferred.

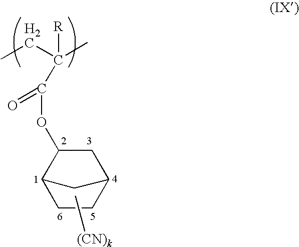

[In the formula (IX′), R represents a hydrogen atom or a lower alkyl group, and k represents an integer from 1 to 3.]

In the formula (IX′), R is as described above for the formulas (I′) to (III′).

Of these units, structural units in which k is 1 are preferred. Furthermore, the cyano group is preferably bonded to position 5 or position 6 of the norbornyl group.

The structural unit (a3) may use either a single structural unit, or a combination of two or more different structural units.

The proportion of the structural unit (a3) within the component (A), relative to the combined total of all the structural units that constitute the component (A), is preferably within a range from 10 to 50 mol %, even more preferably from 15 to 40 mol %, and is most preferably from 20 to 35 mol %. Ensuring that this proportion is at least as large as the lower limit of the above range improves the lithography characteristics, whereas ensuring that the proportion is no greater than the upper limit of the above range enables a favorable balance to be achieved with the other structural units.

The component (A) may include structural units other than the aforementioned structural units (a1) through (a3), but the combined total of these structural units (a1) through (a3), relative to the combined total of all the structural units, is preferably within a range from 70 to 100 mol %, and is even more preferably from 80 to 100 mol %.

The component (A) may include a structural unit (a4) besides the aforementioned structural units (a1) through (a3).

There are no particular restrictions on the structural unit (a4), which may be any other structural unit that cannot be classified as one of the above structural units (a1) through (a3).

For example, structural units that contain a polycyclic aliphatic hydrocarbon group and are derived from an acrylate ester are preferred. The polycyclic aliphatic hydrocarbon group is preferably a group of 4 to 20 carbon atoms, and suitable examples include polycyclic groups selected from amongst the aliphatic cyclic groups exemplified above in relation to the “acid-dissociable, dissolution-inhibiting group that contains an aliphatic cyclic group”. In terms of factors such as industrial availability, one or more groups selected from amongst a tricyclodecanyl group, adamantyl group, tetracyclododecanyl group, norbornyl group, and isobornyl group is particularly preferred. The polycyclic aliphatic hydrocarbon group within the structural unit (a4) is most preferably a non-acid-dissociable group.

Specific examples of the structural unit (a4) include units of the structures (X) to (XII) shown below.

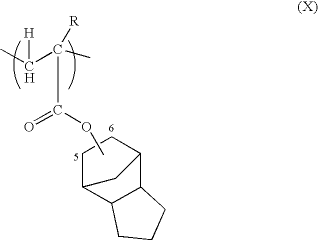

(wherein, R represents a hydrogen atom or a lower alkyl group)

In the formula (X), R is as described above for the formulas (I′) to (III′).

This structural unit typically exists as a mixture of the isomers in which the bonding position is either position 5 or position 6.

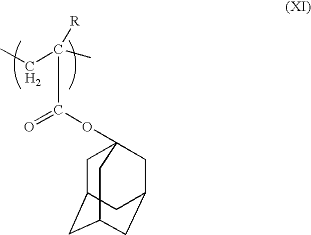

(wherein, R represents a hydrogen atom or a lower alkyl group)

In the formula (XI), R is as described above for the formulas (I′) to (III′).

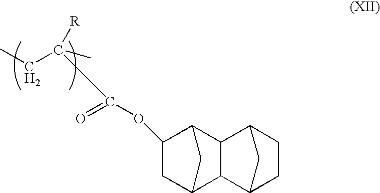

(wherein, R represents a hydrogen atom or a lower alkyl group)

In the formula (XII), R is as described above for the formulas (I′) to (III′).

In those cases where a structural unit (a4) is included, the proportion of the structural unit (a4) within the component (A), relative to the combined total of all the structural units that constitute the component (A), is preferably within a range from 1 to 25 mol %, and is even more preferably from 5 to 20 mol %.

The component (A) is preferably a copolymer that includes at least the structural units (a1), (a2), and (a3). Examples of such copolymers include copolymers formed solely from the aforementioned structural units (a1), (a2) and (a3), and structural units formed from the structural units (a1), (a2), (a3) and (a4).

The component (A) can be obtained, for example, by a conventional radical polymerization or the like of the monomers corresponding with each of the structural units, using a radical polymerization initiator such as azobisisobutyronitrile (AIBN).

The weight average molecular weight (the polystyrene equivalent weight average molecular weight determined by gel permeation chromatography, this also applies below) of the component (A) is typically no more than 30,000, and is preferably no more than 20,000, even more preferably 12,000 or lower, and is most preferably 10,000 or lower.

There are no particular restrictions on the lower limit of the weight average molecular weight, although from the viewpoints of inhibiting pattern collapse and achieving a favorable improvement in resolution and the like, the weight average molecular weight is preferably at least 4,000, and even more preferably 5,000 or greater.

The component (A) may be either a single resin, or a combination of two or more different resins.

The quantity of the component (A) within the resist composition can be adjusted appropriately in accordance with the thickness of the resist film that is to be formed.

The component (B) can use any of the known acid generators used in conventional chemically amplified resist compositions without any particular restrictions. Examples of the types of acid generators that have been used are numerous, and include onium salt-based acid generators such as iodonium salts and sulfonium salts, oxime sulfonate-based acid generators, diazomethane-based acid generators such as bisalkyl or bisaryl sulfonyl diazomethanes, and poly(bis-sulfonyl)diazomethanes, nitrobenzyl sulfonate-based acid generators, iminosulfonate-based acid generators, and disulfone-based acid generators.

Examples of suitable onium salt-based acid generators include compounds represented by general formulas (b-1) and (b-2) shown below.

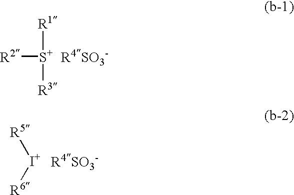

[wherein, R¹″ to R³″, and R⁵″ to R⁶″ each represent, independently, an aryl group or an alkyl group; and R⁴″ represents a straight-chain, branched or cyclic alkyl group or fluoroalkyl group; provided that at least one of R¹″ to R³″ represents an aryl group, and at least one of R⁵″ to R⁶″ represents an aryl group]

In the formula (b-1), R¹″ to R³″ each represent, independently, an aryl group or an alkyl group. Of the groups R¹″ to R³″, at least one group represents an aryl group. Compounds in which at least two of R¹″ to R³″ represent aryl groups are preferred, and compounds in which all of R¹″ to R³″ are aryl groups are the most preferred.

There are no particular restrictions on the aryl groups of R¹″ to R³″, and suitable examples include aryl groups of 6 to 20 carbon atoms, in which either a portion of, or all of, the hydrogen atoms of these aryl groups may be either substituted, or not substituted, with alkyl groups, alkoxy groups, or halogen atoms and the like. In terms of enabling low-cost synthesis, aryl groups of 6 to 10 carbon atoms are preferred. Specific examples of suitable groups include a phenyl group and a naphthyl group.

Alkyl groups that may be used for substitution of the hydrogen atoms of the above aryl groups are preferably alkyl groups of 1 to 5 carbon atoms, and a methyl group, ethyl group, propyl group, n-butyl group or tert-butyl group is the most desirable.

Alkoxy groups that may be used for substitution of the hydrogen atoms of the above aryl groups are preferably alkoxy groups of 1 to 5 carbon atoms, and a methoxy group or ethoxy group is the most desirable. Halogen atoms that may be used for substitution of the hydrogen atoms of the above aryl groups are preferably fluorine atoms.

There are no particular restrictions on the alkyl groups of R¹″ to R³″, and suitable examples include straight-chain, branched, or cyclic alkyl groups of 1 to 10 carbon atoms. From the viewpoint of achieving excellent resolution, alkyl groups of 1 to 5 carbon atoms are preferred. Specific examples include a methyl group, ethyl group, n-propyl group, isopropyl group, n-butyl group, isobutyl group, n-pentyl group, cyclopentyl group, hexyl group, cyclohexyl group, nonyl group, and decanyl group, although in terms of achieving superior resolution and enabling low-cost synthesis, a methyl group is the most desirable.

Of the above possibilities, compounds in which R¹″ to R³″ are all phenyl groups are the most preferred.

The group R⁴″ represents a straight-chain, branched or cyclic alkyl group or fluoroalkyl group.

As the straight-chain alkyl group, groups of 1 to 10 carbon atoms are preferred, groups of 1 to 8 carbon atoms are even more preferred, and groups of 1 to 4 carbon atoms are the most desirable.

Suitable cyclic alkyl groups include the same groups as those listed above in relation to the group R¹″, and cyclic groups of 4 to 15 carbon atoms are preferred, groups of 4 to 10 carbon atoms are even more preferred, and groups of 6 to 10 carbon atoms are the most desirable.

As the above fluoroalkyl group, groups of 1 to 10 carbon atoms are preferred, groups of 1 to 8 carbon atoms are even more preferred, and groups of 1 to 4 carbon atoms are the most desirable. Furthermore, the fluorination ratio of the fluoroalkyl group (namely, the fluorine atom proportion within the alkyl group) is preferably within a range from 10 to 100%, and even more preferably from 50 to 100%, and groups in which all of the hydrogen atoms have been substituted with fluorine atoms yield the strongest acids, and are consequently the most desirable.

The group R⁴″ is most preferably a straight-chain or cyclic alkyl group, or a fluoroalkyl group.

In the formula (b-2), R⁵″ to R⁶″ each represent, independently, an aryl group or an alkyl group. At least one of R⁵″ to R⁶″ represents an aryl group. Compounds in which all of R⁵″ to R⁶″ are aryl groups arc the most preferred.

Suitable examples of the aryl groups of the groups R⁵″ to R⁶″ include the same aryl groups as those described above for the groups R¹″ to R³″.

Suitable examples of the alkyl groups of the groups R⁵″ to R⁶″ include the same alkyl groups as those described above for the groups R¹″ to R³″.

Of the above possibilities, compounds in which R⁵″ to R⁶″ are all phenyl groups are the most preferred.

Suitable examples of the group R⁴″ in the formula (b-2) include the same groups as those described for the group R⁴″ in the aforementioned formula (b-1).

Specific examples of suitable onium salt-based acid generators include diphenyliodonium trifluoromethanesulfonate or nonafluorobutanesulfonate, bis(4-tert-butylphenyl)iodonium trifluoromethanesulfonate or nonafluorobutanesulfonate, triphenylsulfonium trifluoromethanesulfonate, heptafluoropropanesulfonate or nonafluorobutanesulfonate, tri(4-methylphenyl)sulfonium trifluoromethanesulfonate, heptafluoropropanesulfonate or nonafluorobutanesulfonate, dimethyl(4-hydroxynaphthyl)sulfonium trifluoromethanesulfonate, heptafluoropropanesulfonate or nonafluorobutanesulfonate, monophenyldimethylsulfonium trifluoromethanesulfonate, heptafluoropropanesulfonate or nonafluorobutanesulfonate, diphenylmonomethylsulfonium trifluoromethanesulfonate, heptafluoropropanesulfonate or nonafluorobutanesulfonate, (4-methylphenyl)diphenylsulfonium trifluoromethanesulfonate, heptafluoropropanesulfonate or nonafluorobutanesulfonate, (4-methoxyphenyl)diphenylsulfonium trifluoromethanesulfonate, heptafluoropropanesulfonate or nonafluorobutanesulfonate, tri(4-tert-butyl)phenylsulfonium trifluoromethanesulfonate, heptafluoropropanesulfonate or nonafluorobutanesulfonate, and diphenyl(1-(4-methoxy)naphthyl)sulfonium trifluoromethanesulfonate, heptafluoropropanesulfonate or nonafluorobutanesulfonate. Furthermore, onium salts in which the anion portion of the above onium salts has been substituted with a methanesulfonate, n-propanesulfonate, n-butanesulfonate, or n-octanesulfonate can also be used.

Compounds in which the anion portion within the above general formulas (b-1) and (b-2) has been substituted with an anion portion represented by a general formula (b-3) or (b-4) shown below (and in which the cation portion is the same as that shown in (b-1) or (b-2)) can also be used.

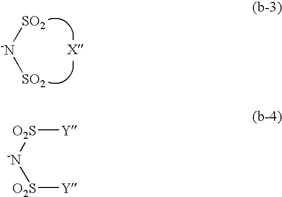

[wherein, X″ represents an alkylene group of 2 to 6 carbon atoms in which at least one hydrogen atom has been substituted with a fluorine atom; and Y″ and Z″ each represent, independently, an alkyl group of 1 to 10 carbon atoms in which at least one hydrogen atom has been substituted with a fluorine atom]

The group X″ is a straight-chain or branched alkylene group in which at least one hydrogen atom has been substituted with a fluorine atom, and the number of carbon atoms within the alkylene group is typically within a range from 2 to 6, preferably from 3 to 5, and is most preferably 3.

Y″ and Z″ each represent, independently, a straight-chain or branched alkyl group in which at least one hydrogen atom has been substituted with a fluorine atom, and the number of carbon atoms within the alkyl group is typically within a range from 1 to 10, preferably from 1 to 7, and is most preferably from 1 to 3.

Within the above ranges for the numbers of carbon atoms, lower numbers of carbon atoms within the alkylene group X″ or the alkyl groups Y″ and Z″ result in better solubility within the resist solvent, and are consequently preferred.

Furthermore, in the alkylene group X″ or the alkyl groups Y″ and Z″, the larger the number of hydrogen atoms that have been substituted with fluorine atoms, the stronger the acid becomes, and the transparency relative to high energy light beams of 200 nm or less or electron beams also improves favorably. The fluorine atom proportion within the alkylene group or alkyl groups, namely the fluorination ratio, is preferably within a range from 70 to 100%, and even more preferably from 90 to 100%, and perfluoroalkylene groups or perfluoroalkyl groups in which all of the hydrogen atoms have been substituted with fluorine atoms are the most desirable.

In the present invention, as the component (B), the use of an onium salt having a fluorinated alkylsulfonate ion as the anion is preferred.

As the component (B), either a single acid generator may be used alone, or a combination of two or more different acid generators may be used.

The quantity of the component (B) within the resist composition is typically within a range from 0.5 to 30 parts by weight, and preferably from 1 to 10 parts by weight, per 100 parts by weight of the component (A). Ensuring the quantity satisfies this range enables satisfactory pattern formation to be conducted. Furthermore, a uniform solution is obtained, and the storage stability is also favorable, both of which are desirable.

In the resist composition, in order to improve the resist pattern shape and the post exposure stability of the latent image formed by the pattern-wise exposure of the resist layer, a nitrogen-containing organic compound (D) (hereafter referred to as the component (D)) may be added as an optional component.

A multitude of these nitrogen-containing organic compounds have already been proposed, and any of these known compounds can be used, although an aliphatic amine, and particularly a secondary aliphatic amine or tertiary lower aliphatic amine is preferred.

Examples of these aliphatic amines include amines in which at least one hydrogen atom of ammonia NH₃ has been substituted with an alkyl group or hydroxyalkyl group of no more than 12 carbon atoms (that is, alkylamines or alkyl alcohol amines). Specific examples of these aliphatic amines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decanylamine, and tri-n-dodecylamine; and alkyl alcohol amines such as diethanolamine, triethanolamine, diisopropanolamine, triisopropanolamine, di-n-octanolamine, and tri-n-octanolamine. Of these, alkyl alcohol amines and trialkyl amines are preferred, and alkyl alcohol amines are the most desirable. Amongst the various alkyl alcohol amines, triethanolamine and triisopropanolamine are the most preferred.

These compounds may be used either alone, or in combinations of two or more different compounds.

The component (D) is typically used in a quantity within a range from 0.01 to 5.0 parts by weight per 100 parts by weight of the component (A).

Furthermore, in order to prevent any deterioration in sensitivity caused by the addition of the above component (D), and improve the resist pattern shape and the post exposure stability of the latent image formed by the pattern-wise exposure of the resist layer, an organic carboxylic acid, or a phosphorus oxo acid or derivative thereof (E) (hereafter referred to as the component (E)) may also be added to the resist composition as another optional component. The component (D) and the component (E) can be used in combination, or either one can also be used alone.

Examples of suitable organic carboxylic acids include malonic acid, citric acid, malic acid, succinic acid, benzoic acid, and salicylic acid.

Examples of suitable phosphorus oxo acids or derivatives thereof include phosphoric acid or derivatives thereof such as esters, including phosphoric acid, di-n-butyl phosphate and diphenyl phosphate; phosphonic acid or derivatives thereof such as esters, including phosphonic acid, dimethyl phosphonate, di-n-butyl phosphonate, phenylphosphonic acid, diphenyl phosphonate, and dibenzyl phosphonate; and phosphinic acid or derivatives thereof such as esters, including phosphinic acid and phenylphosphinic acid, and of these, phosphonic acid is particularly preferred.

The component (E) is typically used in a quantity within a range from 0.01 to 5.0 parts by weight per 100 parts by weight of the component (A).

The resist composition can be produced by dissolving the materials in an organic solvent.

The organic solvent may be any solvent capable of dissolving the various components used to generate a uniform solution, and one or more solvents selected from known materials used as the solvents for conventional chemically amplified resists can be used.

Specific examples of the solvent include lactones such as γ-butyrolactone, ketones such as acetone, methyl ethyl ketone, cyclohexanone, methyl isoamyl ketone and 2-heptanone, polyhydric alcohols and derivatives thereof such as ethylene glycol, ethylene glycol monoacetate, diethylene glycol, diethylene glycol monoacetate, propylene glycol, propylene glycol monoacetate, dipropylene glycol, or the monomethyl ether, monoethyl ether, monopropyl ether, monobutyl ether or monophenyl ether of dipropylene glycol monoacetate, cyclic ethers such as dioxane, and esters such as methyl lactate, ethyl lactate (EL), methyl acetate, ethyl acetate, butyl acetate, methyl pyruvate, ethyl pyruvate, methyl methoxypropionate, and ethyl ethoxypropionate.

These organic solvents may be used either alone, or as a mixed solvent of two or more different solvents.

Furthermore, mixed solvents produced by mixing propylene glycol monomethyl ether acetate (PGMEA) with a polar solvent are preferred. Although the blend ratio (weight ratio) in such mixed solvents can be set in accordance with factors such as the co-solubility of the PGMEA and the polar solvent, the ratio is preferably within a range from 1:9 to 9:1, and is even more preferably from 2:8 to 8:2.

More specifically, in those cases where EL is added as the polar solvent, the weight ratio PGMEA:EL is preferably within a range from 1:9 to 9:1, and is even more preferably from 2:8 to 8:2.

Furthermore, as the organic solvent, mixed solvents containing at least one of PGMEA and EL, together with γ-butyrolactone, are also preferred. In such cases, the weight ratio of the former and latter components in the mixed solvent is preferably within a range from 70:30 to 95:5.

There are no particular restrictions on the quantity used of the organic solvent, although the quantity should be set in accordance with the coating film thickness required, at a concentration that enables favorable application of the solution to a substrate or the like. Typically, the quantity of solvent is set so that the solid fraction concentration of the resist composition falls within a range from 2 to 20% by weight, and preferably from 5 to 15% by weight.

Other miscible additives can also be added to the resist composition according to need, and examples include additive resins for improving the properties of the resist film, surfactants for improving the coating properties, dissolution inhibitors, plasticizers, stabilizers, colorants, halation prevention agents, and dyes.

As described above, by employing the method for forming a resist pattern according to the present invention, pattern collapse can be readily suppressed during the formation of very fine resist patterns such as line and space patterns with a line width of no more than 90 nm, and particularly 65 nm or less.

Furthermore, in the present invention, the effects described above can be obtained simply by conducting the simple operation of restricting the developing time to less than 30 seconds, and preferably no longer than 25 seconds, even more preferably no longer than 20 seconds, and most preferably no longer than 15 seconds, and consequently no special materials or processes need be used, enabling reductions in both the cost and the process time. Furthermore, improvements in the level of throughput can also be expected.

In addition, the depth of focus and the exposure margin are large, and the smallest pattern dimension at which pattern collapse occurs is small. Consequently, the process margins are large.

### EXAMPLES

### Production Example 1 (Preparation of Resist Composition)

100 parts by weight of a resin 1 represented by a formula (1) shown below as the component (A) (in the formula (1), l/m/n/k=40/40/15/5 (molar ratio); weight average molecular weight 6,000, polydispersity 2.3), 4.0 parts by weight of triphenylsulfonium nonafluorobutanesulfonate and 3.5 parts by weight of tri(p-tert-butylphenyl)sulfonium nonafluorobutanesulfonate as the component (B), and 0.6 parts by weight of triethanolamine as the component (D) were dissolved in a mixed solvent of PGMEA and EL (PGMEA/EL=6/4 (weight ratio)), thus completing preparation of a positive resist composition with a solid fraction concentration of 5% by weight.

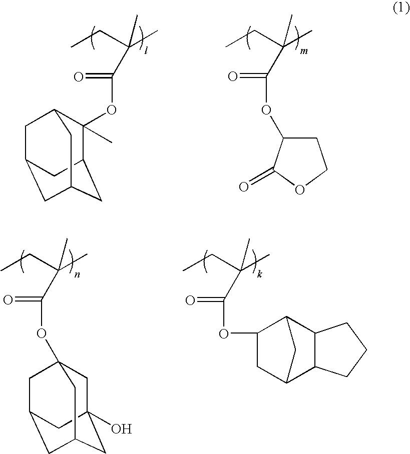

### Example 1, Comparative Examples 1 and 2

Using the positive resist composition obtained in the production example 1, a resist pattern was formed using the procedure described below, and the resist pattern was then evaluated.

First, an organic anti-reflective film composition ARC-29 (a product name, manufactured by Brewer Science Ltd.) was applied to the surface of a silicon wafer using a spinner, and the composition was then baked and dried on a hotplate at 215° C. for 60 seconds, thereby forming an organic anti-reflective film with a film thickness of 77 nm.

The positive resist composition prepared in the production example 1 was applied to the surface of this organic anti-reflective film using a spinner, and was then prebaked (PAB) and dried on a hotplate at 105° C. for 90 seconds, thereby forming a resist film with a film thickness of 125 nm.

Subsequently, the resist film was selectively irradiated with an ArF excimer laser (193 nm) through a mask pattern (a line and space (L/S) pattern with a space width of 60 pm and a pitch of 160 nm), using an ArF exposure apparatus NSR-S306 (manufactured by Nikon Corporation; NA (numerical aperture)=0.78, σ=0.3).

A PEB treatment was then conducted at 110° C. for 90 seconds, and the resist layer was then subjected to developing at 23° C. using an alkali developing solution, for the developing time shown in Table 1. The alkali developing solution used was a 2.38% by weight aqueous solution of tetramethylammonium hydroxide. Following developing, the resist was washed for 20 seconds using pure water and then shaken dry.

Inspection of the L/S pattern obtained in this manner using a scanning electron microscope (SEM) revealed that a L/S pattern with a line width of 50 nm and a pitch of 160 nm had been formed.

### (DOF)

Using the optimum exposure dose FOP (20 mJ/cm²) for the formation of the above L/S pattern, resist pattern formation was conducted in the same manner as above, but with the focal depth offset up or down, and the depth of focus (μm) over which pattern formation could be conducted without pattern collapse was determined. The results are shown in Table 1.

### (Minimum Pattern Width)

The pattern (line width) was narrowed by increasing the exposure dose, and the line width at which pattern collapse started to occur was determined by observation using an SEM. The line width (nm) immediately prior to the point where pattern collapse occurred is recorded in Table 1 as the “minimum pattern width”.

TABLE 1

| | Developing time | DOF | Minimum pattern |
|---|---|---|---|
| | (seconds) | (μm) | width (nm) |
| Example 1 | 15 | 0.45 | 33.4 |
| Comparative example 1 | 30 | 0.40 | 40.9 |
| Comparative example 2 | 300 | 0.35 | 38.0 |

As is evident from the above results, in the example 1, where the developing time was 15 seconds, the DOF was excellent. Furthermore, the width at which pattern collapse occurred was very small, and for example, pattern collapse did not occur even at a pattern width approximately 20% narrower than the comparative example 1. Moreover, the pattern shape was also favorable with a high degree of rectangular formability. Furthermore, the example 1 also exhibited a superior exposure margin to the comparative example 1 and the comparative example 2.

In contrast, in the comparative example 1 and the comparative example 2, where the developing times were 30 seconds and 300 seconds respectively, the DOF (depth of focus) was narrower than that of the example 1, and pattern collapse occurred at a thicker line width than that observed for the example 1. In addition, in the comparative example 2, the formed pattern exhibited swelling.

### INDUSTRIAL APPLICABILITY

A method for forming a resist pattern can be provided that enables pattern collapse during the formation of very fine patterns to be readily prevented.

1. A method for forming a resist pattern comprising the steps of:
forming a resist film on a substrate using a resist composition including a resin component (A) that exhibits changed alkali solubility under action of acid and an acid generator component (B) that generates acid upon exposure;
selectively exposing said resist film; and
developing said resist film using an alkali developing solution for a developing time of less than 30 seconds, thereby forming a resist pattern.

2. A method for forming a resist pattern according to claim 1, wherein said exposure is conducted using an ArF excimer laser.

3. A method for forming a resist pattern according to claim 2, wherein said resin component (A) includes a structural unit (a) derived from an acrylate ester.

4. A method for forming a resist pattern according to claim 3, wherein said resin component (A) includes a structural unit (a1) derived from an acrylate ester that contains an acid-dissociable, dissolution-inhibiting group.

5. A method for forming a resist pattern according to claim 4, wherein said resin component (A) includes a structural unit (a2) derived from an acrylate ester that contains a lactone ring.

6. A method for forming a resist pattern according to claim 4, wherein said resin component (A) includes a structural unit (a3) derived from an acrylate ester that contains a polar group-containing polycyclic group.

7. A method for forming a resist pattern according to claim 5, wherein said resin component (A) includes a structural unit (a3) derived from an acrylate ester that contains a polar group-containing polycyclic group.

8. A method for forming a resist pattern according to any one of claim 1 through claim 7, wherein said resist composition also includes a nitrogen-containing organic compound.
